(19) United States
(12) Patent Application Publication
(10) Pub. No.: US 2015/0023784 A1
(43) Pub. Date: Jan. 22, 2015

(54) ROTATION DRIVE DEVICE

(71) Applicant: Sony Corporation, Tokyo (JP)

(72) Inventor: Akihiko Koizumi, Nagano (JP)

(21) Appl. No.: 14/317,586

(22) Filed: Jun. 27, 2014

(30) Foreign Application Priority Data
Jul. 22, 2013 (JP) 2013-151432

(51) Int. Cl. F04D 29/053; H05K 7/20; H05K 5/02

(52) U.S. Cl. CPC F04D 29/053; H05K 5/0217; H05K 7/20136
USPC 415/122.1; 464/170

(57) ABSTRACT

Provided is a rotation drive device including a shaft member extending in a first direction, and a rotating object configured to allow the shaft member to be inserted in the rotating object, and configured to rotate around an axis of rotation extending in the first direction relative to the shaft member. Opposite ends of the shaft member are fixedly joined to respective inner surfaces of a first partition wall and a second partition wall located on the opposite sides in the first direction of the rotating object.

### CROSS REFERENCE TO RELATED APPLICATIONS

This application claims the benefit of Japanese Priority Patent Application JP 2013-151432 filed Jul. 22, 2013, the entire contents of which are incorporated herein by reference.

### BACKGROUND

The present disclosure relates to rotation drive devices.

In the field of portable electronic apparatuses such as laptop or notebook personal computers (PCs) etc., there has in recent years been a demand for a technology for efficiently dissipating heat generated in the apparatus to the outside because of the increasing integration degree and speed of integrated circuits such as a central processing unit (CPU) etc. provided in the apparatus. For example, JP 2007-122132A discloses a portable electronic apparatus in which a space for thermal insulation is provided between a heat source, such as a CPU etc., and a battery, and a rotation drive device, such as a cooling fan, which is driven to rotate, thereby causing air to flow, is used to draw air in from the thermal insulation space and then expel the air toward the outside.

### SUMMARY

On the other hand, in the field of portable electronic apparatuses such as laptop or notebook PCs etc., there has in recent years been a demand for a smaller and lighter housing, and the partition walls of the housing has tended to be thinner. As the partition wall is thinner, the rigidity of the housing decreases. Therefore, if pressure is externally exerted on the housing, the partition wall of the housing is likely to be deformed, resulting in an influence on the internal configuration. However, in the technology described in JP 2007-122132A, the influence of such deformation of the partition wall of the housing is not sufficiently taken into consideration. Therefore, in the technology described in JP 2007-122132A, when external pressure is exerted on the housing, the rotation drive device for thermal dissipation is likely to fail to smoothly operate due to the deformed partition wall, leading to a decrease in the efficiency of thermal dissipation (cooling efficiency).

Under these circumstances, there has been a demand for a more reliable rotation drive device which maintains the normal operation even external pressure is exerted thereon. Therefore, the present disclosure proposes a novel and improved rotation drive device which can operate with higher reliability against external pressure.

According to an embodiment of the present disclosure, there is provided a rotation drive device including a shaft member extending in a first direction, and a rotating object configured to allow the shaft member to be inserted in the rotating object, and configured to rotate around an axis of rotation extending in the first direction relative to the shaft member. Opposite ends of the shaft member are fixedly joined to respective inner surfaces of a first partition wall and a second partition wall located on the opposite sides in the first direction of the rotating object.

According to the present disclosure, the opposite ends of the shaft member inserted in the rotating object are fixedly joined to the inner surfaces of the first and second partition walls located on the opposite sides in the first direction of the rotating object, on the opposite sides in the first direction in which the shaft member is extended. Therefore, the shaft member has the function of supporting the rotating object for rotation and supporting the first and second partition walls from the inside. Therefore, the rigidity of the first and second partition walls against external pressure exerted from the first direction is improved, and therefore, the deformation of the first and second partition walls due to the external pressure is reduced or prevented. Therefore, the normal operation of the rotation drive device is maintained even when external pressure is exerted thereon.

As described above, according to the present disclosure, the reliability of operation against external pressure can be further improved.

### BRIEF DESCRIPTION OF THE DRAWINGS

FIG. 1 is a schematic cross-sectional view showing a commonly used cooling fan, taken along a plane including the axis of rotation of the fan;

FIG. 2A is a diagram for describing a case where external pressure is exerted on a commonly used cooling fan;

FIG. 2B is a diagram for describing a case where external pressure is exerted on a commonly used cooling fan;

FIG. 3 is a diagram for describing an example configuration of a commonly used cooling fan in which a buffer member is provided between a housing of a portable electronic apparatus and a cooling fan;

FIG. 4 is a schematic cross-sectional view showing a cooling fan according to an embodiment of the present disclosure, taken along a plane including the axis of rotation of the fan; and

FIG. 5 is a diagram for describing advantages obtained by the cooling fan of this embodiment.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Note that the description will be given in the following order.

1. Commonly Used Existing Cooling Fan
1-1. Configuration of Commonly Used Existing Cooling Fan
1-2. Study of Commonly Used Existing Cooling Fan

2. Cooling Fan of This Embodiment
2-1. Configuration of Cooling Fan of This Embodiment
2-2. Advantages of Cooling Fan of This Embodiment

3. Summary

### <1. Commonly Used Existing Cooling Fan>

Firstly, in order to clearly describe the present disclosure, how the present inventors have discovered the present disclosure will be described in detail. In the description that follows, a commonly used cooling fan will be described as an example commonly used rotation drive device, assuming that the rotation drive device is provided in a housing of a portable electronic apparatus, such as a notebook PC etc. In the commonly used cooling fan, a fan, which is a rotating object, is driven to rotate, so that the flow of air occurs around the fan, whereby heat is dissipated from the inside of the housing toward the outside of the housing.

### [1-1. Configuration of Commonly Used Existing Cooling Fan]

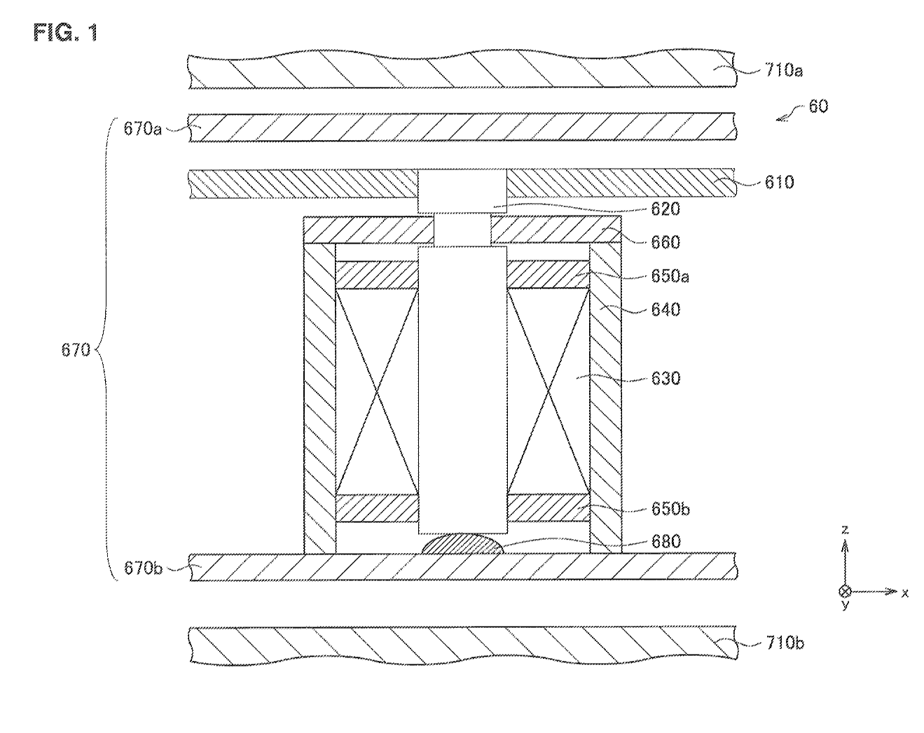

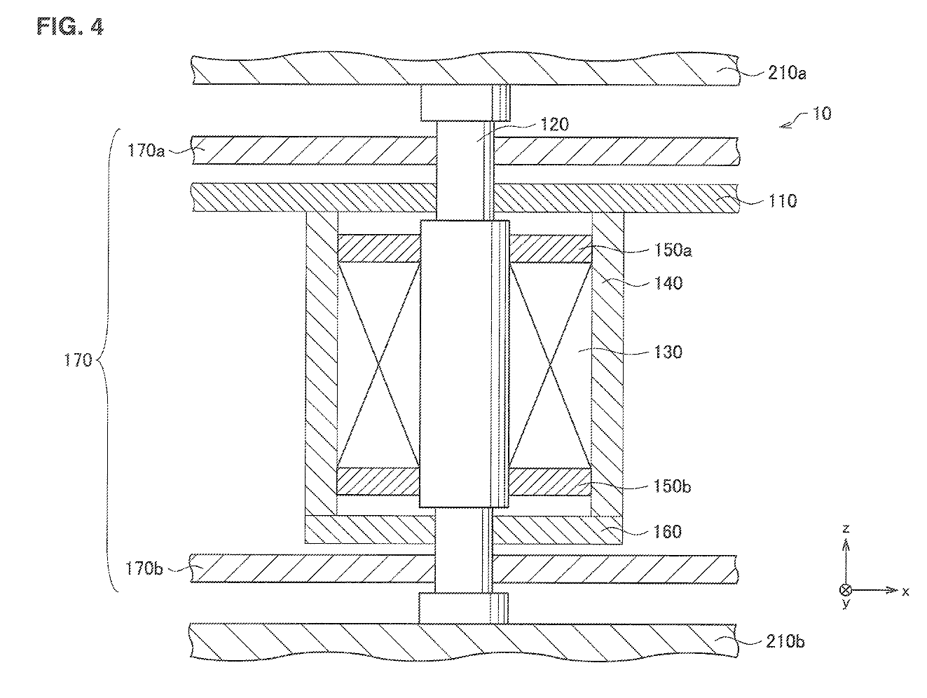

Firstly, a configuration of the commonly used existing cooling fan will be outlined with reference to FIG. 1. FIG. 1 is a schematic cross-sectional view showing the commonly used cooling fan, taken along a plane including the axis of rotation of the fan. Note that, in FIG. 1 and FIG. 4 described below, for the sake of clarity, the components of the cooling fan may not be illustrated to scale. The relationship in size between each component of the cooling fan shown in FIGS. 1 and 4 does not necessarily represent an exact relationship in size between each component in the actual cooling fan.

Referring to FIG. 1, the commonly used cooling fan 60 includes a fan (rotating object) 610, a shaft member 620, a bearing 630, a housing 640, O-rings 650a and 650b, a cap 660, a case 670, and a thrust bearing 680. Other components are housed in the case 670.

In the description that follows, as shown in FIG. 1, a direction in which the shaft member 620 extends in the case 670 is defined as a z-axis direction. Two directions which are perpendicular to each other in a plane perpendicular to the z-axis direction are defined as an x-axis direction and a y-axis direction. The z-axis direction may also be referred to as a vertical direction, and the positive direction of the z axis may also be referred to as an upward direction, and the negative direction of the z axis may also be referred to as a downward direction.

The case 670 includes an upper case partition wall 670a and a lower case partition wall 670b, only a portion of which is shown in FIG. 1. FIG. 1 also shows an upper housing partition wall 710a and a lower housing partition wall 710b of a housing of the portable electronic apparatus housing the cooling fan 60, that are provided above the upper case partition wall 670a and below the lower case partition wall 670b, respectively. In the description that follows, the upper case partition wall 670a and/or the upper housing partition wall 710a which are located above the fan 610 are also referred to as “first partition walls,” and the lower case partition wall 670b and/or the lower housing partition wall 710b which are located below the fan 610 are also referred to as “second partition walls.”

The fan 610, which has a generally disk-like shape, includes a plurality of blades in an outer circumferential portion of the disk along the outer circumstance of the disk. FIG. 1 shows only substantially the center portion and the surrounding portion of the fan 610, but not the outer circumferential portion in which the blades are provided. As shown in FIG. 1, the fan 610 is placed so that the top/bottom surface of the disk is substantially parallel to the plane (x-y plane) defined by the x axis and the y axis. When the fan 610 is driven to rotate around the axis of rotation extending in the z-axis direction which is substantially perpendicular to the top/bottom surface of the disk, the flow of air occurs around the fan 610 by the blades provided in the outer circumferential portion. The shape, arrangement, angle, etc. of the blades provided in the outer circumferential portion of the fan 610 are designed so that air around the fan 610 is drawn in from one direction and then expelled in the opposite direction.

Thus, air in the portable electronic apparatus is drawn in by the cooling fan 60, and is then expelled from the apparatus by the rotation of the fan 610, whereby the effect of cooling the inside of the apparatus is obtained. Therefore, the case 670 has a suitable opening for drawing in air and a suitable opening for expelling air. For example, when the cooling fan 60 is applied to a commonly used notebook PC, in many cases air is drawn in from the vertical direction toward the fan 610, and is then expelled by the rotation of the fan 610 in one direction parallel to the x-y plane. Therefore, the upper and lower case partition walls 670a and 670b may have a suitable opening (not shown) for drawing in air. A side wall of the case 670 may have a suitable opening for expelling air.

The shaft member 620 is a bar-like member which is provided in the case 670, extending in a predetermined direction (the z-axis direction in the example of FIG. 1, and also hereinafter referred to as a “first direction”). The top/bottom surface of the disk-like shape of the fan 610 has an opening facing in the z-axis direction at substantially the center portion thereof. The shaft member 620 is inserted in the opening to be fixedly joined to the fan 610. In the example of FIG. 1, the opening of the fan 610 is fixedly fitted to the shaft member 620. When the shaft member 620 rotates around the axis of rotation extending in the z-axis direction, the fan 610 also rotates around the axis of rotation extending in the z-axis direction. Thus, in the commonly used cooling fan 60, the fan 610 and the shaft member 620 rotate together. Although not shown in FIG. 1, the cooling fan 60 may include a drive arrangement for driving the fan 610 and the shaft member 620 to rotate. Any drive arrangement for use in a commonly used existing cooling fan may be employed, including a motor etc.

In the commonly used cooling fan 60, the shaft member 620 supports an inner surface of the case 670 at only one end thereof. In the example of FIG. 1, a lower end in the z-axis direction of the shaft member 620 supports an inner surface of the lower case partition wall 670b with the thrust bearing 680 being interposed therebetween. On the other hand, the fan 610 is fitted to an upper end in the z-axis direction of the shaft member 620, and the upper end of the shaft member 620 is not in contact with an inner surface of the upper case partition wall 670a.

The housing 640, which has a cylindrical shape in which a space is provided, is located around the shaft member 620, extending in the z-axis direction, to cover the shaft member 620. A lower end of the housing 640 is fixedly joined to the inner surface of the lower case partition wall 670b. The housing 640 and the lower case partition wall 670b may be integrally formed.

The bearing 630 is located between and in contact with an outer circumferential surface of the shaft member 620 and an inner surface of the housing 640. The bearing 630 is, for example, a plain bearing. The bearing 630 allows the shaft member 620 to rotate relative to the housing 640. The bearing 630 may be any of various commonly used known bearings.

In the housing 640, the O-rings 650a and 650b are located above and below the bearing 630, respectively. The bearing 630 is filled with a lubricant, such as grease etc., in order to maintain a smooth operation of the bearing 630. The O-rings 650a and 650b are located to sandwich the bearing 630 from the top and bottom, thereby reducing or preventing external leakage of the lubricant. The cap 660 is provided at an upper end of the housing 640 to close the opening at the upper end in order to reduce or prevent entrance of foreign matter, such as dust etc., into the housing 640, i.e., the bearing 630.

The thrust bearing 680 is provided between the lower end of the shaft member 620 and the inner surface of the lower case partition wall 670b. The thrust bearing 680 can rotate relative to the lower case partition wall 670b while supporting the lower case partition wall 670b. Note that FIG. schematically shows the thrust bearing 680, but not a detailed structure thereof. The thrust bearing 680 may be any of various commonly used known bearings.

The configuration of the commonly used existing cooling fan 60 has been described above with reference to FIG. 1. As described above, in the commonly used cooling fan 60, only one end of the shaft member 620 supports the case 670. In the commonly used cooling fan 60, the fan 610 and the shaft member 620 rotate together. Note that, in FIG. 1, the outlines of members which are driven to rotate around the axis of rotation extending in the z-axis direction when the cooling fan 60 is operated are indicated by a thin line, while the outlines of members which are not driven to rotate are indicated by a thick line.

### [1-2. Study of Commonly Used Existing Cooling Fan]

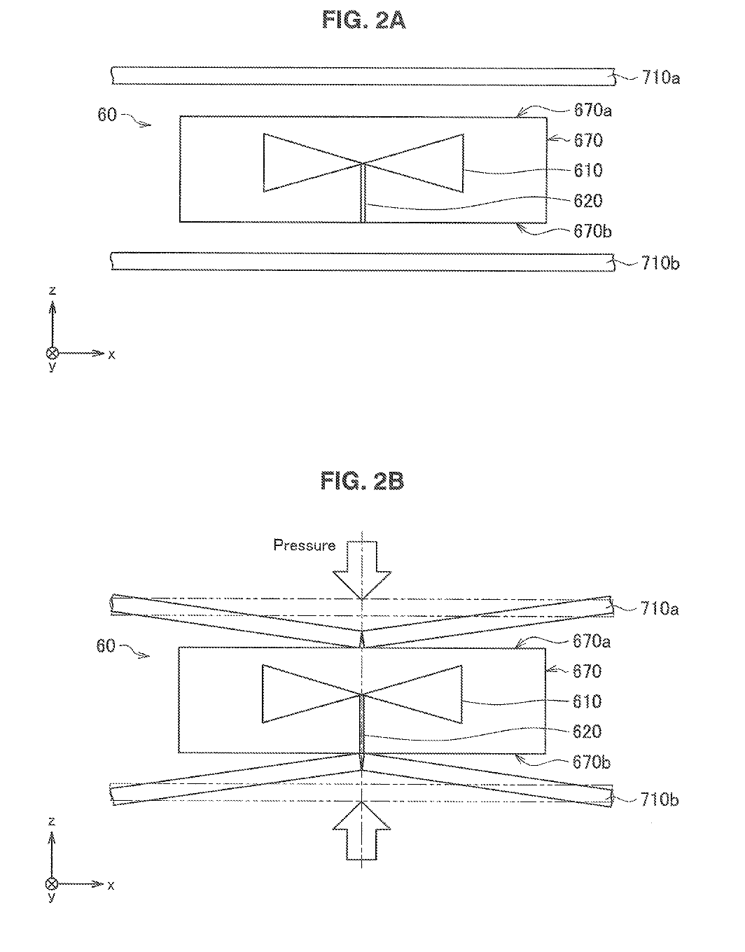

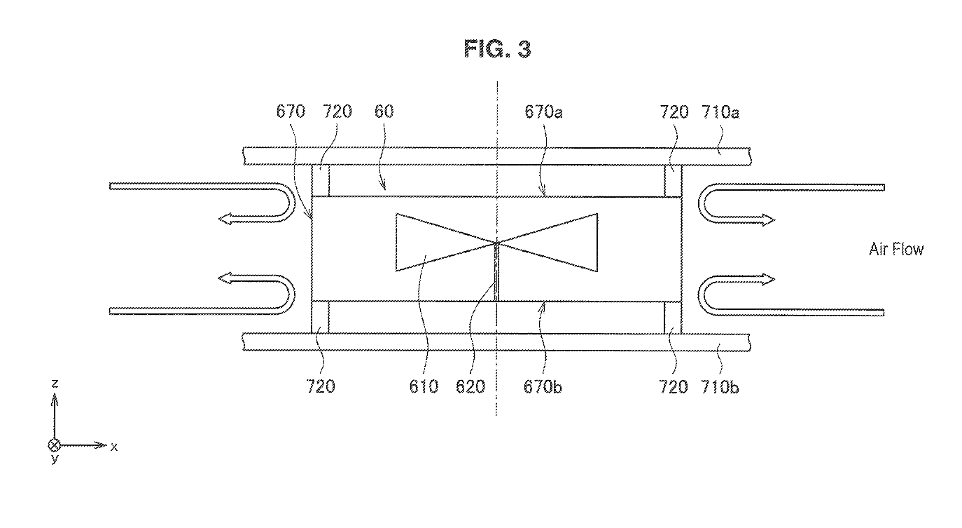

Next, the present inventors' findings on the commonly used cooling fan 60 will be described with reference to FIGS. 2A, 2B, and 3.

FIGS. 2A and 2B are diagrams for describing a case where external pressure is exerted on a commonly used cooling fan. Note that FIGS. 2A and 2B schematically show a simplification of the cooling fan 60 of FIG. 1. Specifically, in FIGS. 2A and 2B, of the components of the cooling fan 60, only the fan 610, the shaft member 620, and the case 670 are schematically shown. The upper and lower housing partition walls 710a and 710b of the housing of the portable electronic apparatus housing the cooling fan 60 are illustrated above and below the cooling fan 60, respectively.

FIG. 2A shows the cooling fan 60 on which external pressure is not being exerted. The portable electronic apparatus in which the cooling fan 60 is provided may be, for example, a notebook PC. Various operation means (operation units), such as a keyboard, a touchpad, etc., which are used by the user to enter an operation input to the notebook PC, may be provided on an upper surface (outer surface) of the upper housing partition wall 710a. When the notebook PC is used, the keyboard, touchpad, etc. is struck or pressed by the user. When the notebook PC is placed on a desk etc. in use, a vertical reaction force from the desk may be exerted on the lower housing partition wall 710b due to the user's operation, such as striking, pressing, etc. Thus, when the portable electronic apparatus, such as a notebook PC etc., is used, external pressure may be exerted on the upper and lower housing partition walls 710a and 710b.

FIG. 2B shows the cooling fan 60 on which external pressure is being exerted. In FIG. 2B, external pressure exerted on the upper and lower housing partition walls 710a and 710b is schematically shown by arrows. When external pressure is exerted on the upper and lower housing partition walls 710a and 710b, the upper and lower housing partition walls 710a and 710b may be deformed or distorted due to the external pressure. In FIG. 2B, the distortion of the upper and lower housing partition walls 710a and 710b is exaggerated. As shown in FIG. 2B, a portion corresponding to the cooling fan 60 of the upper and lower housing partition walls 710a and 710b is deformed due to external pressure, the case 670 of the cooling fan 60 may be pressed by the deformed upper and lower housing partition walls 710a and 710b.

Here, as described above with reference to FIG. 1, in the cooling fan 60, the shaft member 620 supports only the lower case partition wall 670b, and is not in contact with the upper case partition wall 670a. Therefore, a force which is exerted on the case 670 from the vertical direction may be supported only by the side wall of the case 670. Therefore, if the rigidity of the case 670 is not high enough, then when the case 670 is pressed due to the distortion of the upper and lower housing partition walls 710a and 710b, the case 670 may also be deformed, and therefore, the normal operation of the cooling fan 60 may be hindered or prevented. For example, when the case 670 is pressed, an unexpected force may be externally exerted on the shaft member 620, so that the normal operation of the fan 610 may be hindered, or the case 670 and/or a component(s) of the case 670 may be damaged. In some commonly used cooling fans 60, the case 670 is open at the top, i.e., the upper case partition wall 670a is not provided. When the upper case partition wall 670a is not provided, the upper housing partition wall 710a deformed due to external pressure may be directly in contact with the fan 610, the shaft member 620, etc., leading to a more serious operational failure.

As described above with reference to FIGS. 2A and 2B, for the commonly used cooling fan 60, there has been a demand for a configuration which can withstand external pressure in the vertical direction.

Under these circumstances, a configuration has been proposed in which a buffer member is provided between each of the upper and lower housing partition walls 710a and 710b and the cooling fan 60 to support these components. An example of such a configuration in which a buffer member is provided between each of the upper and lower housing partition walls 710a and 710b and the cooling fan 60 is shown in FIG. 3. FIG. 3 is a diagram for describing an example configuration of the commonly used cooling fan 60 in which a buffer member is provided between the housing of the portable electronic apparatus and the cooling fan 60.

Referring to FIG. 3, a buffer member 720 is provided between the case 670 of the cooling fan 60 and each of the upper and lower housing partition walls 710a and 710b. As shown in FIG. 3, there may be a plurality of the buffer members 720. The buffer member 720 is, for example, formed of an elastic member, such as rubber, sponge, etc. Even if the upper and lower housing partition walls 710a and 710b are deformed due to external pressure, the amount of a displacement due to the deformation is accommodated by the elastic deformation of the buffer member 720, whereby an influence of the deformation of the upper and lower housing partition walls 710a and 710b on the case 670 can be reduced. Thus, by providing the buffer member 720, even when external pressure is exerted on the upper and lower housing partition walls 710a and 710b, the normal operation of the cooling fan 60 may be maintained.

However, as described above, for example, in the cooling fan 60 used in a notebook PC, in many cases air is drawn in from the vertical direction through the openings provided in the upper and lower case partition walls 670a and 670b. Therefore, a space between the case 670 of the cooling fan 60 and each of the upper and lower housing partition walls 710a and 710b may be a flow channel of air when air is drawn in. Therefore, as shown in FIG. 3, if the buffer member 720 is provided between the case 670 of the cooling fan 60 and each of the upper and lower housing partition walls 710a and 710b, the flow channel may be narrowed or blocked by the buffer member 720, and therefore, air is unlikely to be smoothly drawn into the cooling fan 60. If air is not sufficiently smoothly drawn into the cooling fan 60, the flow rate of air expelled from the portable electronic apparatus (notebook PC) also decreases, resulting in a decrease in the efficiency of dissipating heat to the outside (thermal dissipation efficiency or cooling efficiency). In FIG. 3, a portion of the flow of air around the cooling fan 60 is schematically shown by arrows.

Thus, as described above with reference to FIG. 3, in the commonly used cooling fan 60, by providing the buffer member 720, the influence of external pressure exerted on the housing from the vertical direction on the cooling fan 60 may be reduced. However, the buffer member 720 may physically limit the flow channel through which air is drawn into the cooling fan 60, and therefore, air is unlikely to be smoothly drawn into the cooling fan 60.

The commonly used existing cooling fan 60 has been described above with reference to FIGS. 1, 2A, 2B, and 3. With the above circumstances in mind, after studying a more reliable rotation drive device, the present inventors have arrived at a rotation drive device according to an embodiment of the present disclosure in which even when external pressure is exerted thereon, the normal operation is maintained and the performance of drawing in air and expelling air is not deteriorated. A preferred embodiment of the present disclosure will now be described in detail.

### <2. Cooling Fan According to This Embodiment>

A rotation drive device according to a preferred embodiment of the present disclosure will be described. In the description that follows, it is, for example, assumed that the rotation drive device of the preferred embodiment of the present disclosure is a cooling fan which is provided in a housing of a notebook PC, which is a portable electronic apparatus. In the rotation drive device of the preferred embodiment of the present disclosure, a fan, which is a rotating object, is driven to rotate so that the flow of air occurs around the fan, whereby heat is dissipated from the inside of the housing toward the outside of the housing.

### [2-1. Configuration of Cooling Fan of This Embodiment]

A configuration of the rotation drive device of the preferred embodiment of the present disclosure will be outlined with reference to FIG. 4. FIG. 4 is a schematic cross-sectional view showing a fan in the rotation drive device of the preferred embodiment of the present disclosure, taken along a plane including the axis of rotation of the fan.

Referring to FIG. 4, a cooling fan 10 according to this embodiment includes a fan (rotating object) 110, a shaft member 120, a bearing 130, a housing 140, O-rings 150a and 150b, a cap 160, and a case 170. Of these components, the fan 110, the shaft member 120, the bearing 130, the housing 140, the O-rings 150a and 150b, and the cap 160 are housed in the case 170. The shaft member 120 extends in a first direction and penetrates through the case 170 in the first direction.

In the description that follows, the cooling fan 10 will be described using coordinates defined as in FIG. 1. Specifically, as shown in FIG. 4, a direction (first direction) in which the shaft member 120 extends is defined as a z-axis direction. Two directions which are perpendicular to each other in a plane perpendicular to the z-axis direction are defined as an x-axis direction and a y-axis direction. The z-axis direction may also be referred to as a vertical direction, and the positive direction of the z axis may also be referred to as an upward direction, and the negative direction of the z axis may also be referred to as a downward direction.

In FIG. 4, similar to FIG. 1, the case 170 includes an upper case partition wall 170a and a lower case partition wall 170b, only a portion of which is shown. FIG. 4 also shows an upper housing partition wall 210a and a lower housing partition wall 210b of a housing of a portable electronic apparatus housing the cooling fan 10, that are provided above the upper case partition wall 170a and below the lower case partition wall 170b, respectively. Note that, in this embodiment, of the partition walls of the case 170, the upper case partition wall 170a may not be provided in some applications of the cooling fan 10. In the description that follows, the upper case partition wall 170a and/or the upper housing partition wall 210a which are located above the fan 110 are also referred to as “first partition walls,” and the lower case partition wall 170b and/or the lower housing partition wall 210b which are located below the fan 110 are also referred to as “second partition walls.”

The fan 110, which has a generally disk-like shape, includes a plurality of blades in an outer circumferential portion of the disk along the outer circumstance of the disk. FIG. 4 shows only substantially the center portion and the surrounding portion of the fan 110, but not the outer circumferential portion in which the blades are provided. As shown in FIG. 4, the fan 110 is placed so that the top/bottom surface of the disk is parallel to the x-y plane. In other words, the upper and lower case partition walls 170a and 170b are located on the opposite sides in the vertical direction (first direction) of the fan 110. When the fan 110 is driven to rotate around the axis of rotation extending in the z-axis direction which is substantially perpendicular to the top/bottom surface of the disk, the flow of air occurs around the fan 110 by the blades provided in the outer circumferential portion. The shape, arrangement, angle, etc. of the blades are designed so that air around the fan 110 is drawn in from one direction and then expelled in the opposite direction when the fan 110 is driven to rotate. Thus, the fan 110 has the function of drawing in air from one direction and then expelling the air in the opposite direction when the fan 110 is driven to rotate.

Thus, air in the portable electronic apparatus is drawn in by the cooling fan 10, and the drawn air is expelled from the apparatus by the rotation of the fan 110, resulting in the effect of cooling the inside of the apparatus. Therefore, the case 170 has a suitable opening for drawing in air and a suitable opening for expelling air. Here, for example, in the cooling fan 10, air is drawn in from the vertical direction toward the fan 110, and is then expelled by the rotation of the fan 110 in one direction parallel to the x-y plane. Therefore, the upper and lower case partition walls 170a and 170b may have a suitable opening (not shown) for drawing in air. A side wall of the case 170 may have a suitable opening for expelling air. Thus, air in the portable electronic apparatus is drawn into the cooling fan 10, and the drawn air is expelled from the apparatus by the rotation of the fan 110, resulting in the effect of cooling the inside of the apparatus.

The shaft member 120 is a bar-like member which extends in the first direction. The shaft member 120 penetrates through the case 170 in the first direction. Specifically, the shaft member 120 is inserted in the openings of the upper and lower case partition walls 170a and 170b in the vertical direction, penetrating through the case 170. Opposite ends in the first direction of the shaft member 120 are fixedly joined to inner surfaces of the upper and lower housing partition walls 210a and 210b. Therefore, the shaft member 120 has the function of supporting, in the vertical direction, the housing of the portable electronic apparatus in which the cooling fan 10 is housed.

The shaft member 120 may be fixedly joined to the upper and lower case partition walls 170a and 170b. Specifically, in the openings of the upper and lower case partition walls 170a and 170b in which the shaft member 120 is inserted, an outer circumferential surface of the shaft member 120 may be fixedly joined to inner circumferential surfaces of the openings. Because the shaft member 120 is fixedly joined to the upper and lower case partition walls 170a and 170b, the shaft member 120 has the function of supporting the case 170 as well as the housing of the portable electronic apparatus in the vertical direction.

Although, in the example of FIG. 4, the shaft member 120 penetrates through the case 170 in the vertical direction, and the opposite ends of the shaft member 120 are fixedly joined to the inner surfaces of the upper and lower housing partition walls 210a and 210b, this embodiment is not limited to this example. For example, the shaft member 120 may extend in the case 170, and the opposite ends of the shaft member 120 may be fixedly joined to respective corresponding inner surfaces of the upper and lower case partition walls 170a and 170b. When the opposite ends of the shaft member 120 are fixedly joined to the respective corresponding inner surfaces of the upper and lower case partition walls 170a and 170b, the shaft member 120 can support the case 170 in the vertical direction. Thus, in this embodiment, the opposite ends of the shaft member 120 may be fixedly joined to the upper and lower case partition walls 170a and 170b of the case 170, or alternatively, to the upper and lower housing partition walls 210a and 210b located outside the case 170 of the housing of the portable electronic apparatus in which the cooling fan 10 is provided.

For example, when the case 170 is not provided with the upper case partition wall 170a, the upper end of the shaft member 120 may be fixedly joined to the upper housing partition wall 210a, and the lower end of the shaft member 120 may be fixedly joined to the lower case partition wall 170b. Also, for example, the shaft member 120 may penetrate through the case 170 only in the downward direction, and the upper end of the shaft member 120 may be fixedly joined to the upper case partition wall 170a, and the lower end of the shaft member 120 may be fixedly joined to the lower housing partition wall 210b.

Thus, in this embodiment, the shaft member 120 is provided to support the case 170 and/or the housing of the portable electronic apparatus in the vertical direction. The upper end (one end) of the shaft member 120 may be fixedly joined to the upper case partition wall 170a and/or the upper housing partition wall 210a, and the lower end (the other end) of the shaft member 120 may be fixedly joined to the lower case partition wall 170b and/or the lower housing partition wall 210b.

The top/bottom surface of the disk-like shape of the fan 110 has an opening at substantially the center portion thereof, and the shaft member 120 is inserted in the opening. The fan 110 is allowed to rotate around the axis of rotation extending in the first direction relative to the shaft member 120. For example, a member (not shown.), such as a bearing etc., may be provided between the fan 110 and the shaft member 120 in order to allow the fan 110 to rotate relative to the shaft member 120. Thus, in this embodiment, the opposite ends of the shaft member 120 are fixedly joined to an inner surface of a partition wall of the case 170 or the housing of the portable electronic apparatus. Therefore, when the fan 110 rotates, the shaft member 120 does not rotate. Note that the shaft member 120 may support the fan 110 while reducing or preventing movement of the fan 110 in the z-axis direction. For example, the fan 110 and/or the shaft member 120 may be provided with a member (not shown), such as a stopper etc., which reduces or prevents movement of the fan 110 in the z-axis direction.

Although not shown in FIG. 4, the cooling fan 10 may include a drive arrangement for driving the fan 110 to rotate. The drive arrangement includes, for example, a coil, a substrate or power supply unit for applying a current to the coil, a magnet (or an electromagnet) facing the coil of the fan 110, etc. For example, by causing the coil to operate as an electromagnet by changing the current applied to the coil with a predetermined period and amplitude, the fan 110 can be rotated by an interaction between that electromagnet and the magnet provided in the fan 110. Note that the drive arrangement provided in the cooling fan 10 is not limited to this example. Various drive arrangements used in commonly used existing cooling fans may be applicable to the cooling fan 10. The drive arrangement may be provided outside the cooling fan 10.

The housing 140, which has a cylindrical shape in which a space is provided, is located around the shaft member 120, extending in the z-axis direction, to cover the shaft member 120. In this embodiment, an upper end of the housing 140 may be fixedly joined to a lower surface of the fan 110. Therefore, in this embodiment, the fan 110 and the housing 140 rotate together.

The bearing 130 is located between and in contact with the outer circumferential surface of the shaft member 120 and an inner surface of the housing 140. The bearing 130 is, for example, a plain bearing. The bearing 130 allows the housing 140 to rotate relative to the shaft member 120. Note that the bearing 130 may be any of various commonly used known bearings. The configuration and type of the bearing 130 are not particularly limited. The bearing 130 may be suitably adapted to allow the housing 140 to smoothly rotate relative to the shaft member 120.

In the housing 140, the O-rings 150a and 150b are located above and below the bearing 130, respectively. The bearing 130 is filled with a lubricant, such as grease etc., in order to maintain a smooth operation of the bearing 130. The O-rings 150a and 150b are located to sandwich the bearing 130 from the top and bottom, thereby reducing or preventing external leakage of the lubricant.

The cap 160 is provided at a lower end of the housing 140 to close the opening at the lower end in order to reduce or prevent entrance of foreign matter, such as dust etc., into the housing 140, i.e., the bearing 130. The cap 160 may be fixedly joined to the opening at the lower end of the housing 140. Therefore, in this embodiment, the cap 160 also rotates together with the fan 110 and the housing 140. As shown in FIG. 4, an opening is provided at substantially the center portion of the cap 160, and the shaft member 120 is inserted in the opening, so that the shaft member 120 penetrates through the cap 160 in the vertical direction. A suitable lubricant, bearing, etc. which allows the cap 160 to smoothly rotate relative to the shaft member 120 may be provided at a portion where an inner circumferential surface of the opening of the cap 160 is in contact with the outer circumferential surface of the shaft member 120. Note that, in FIG. 4, the outlines of members which are driven to rotate around the axis of rotation extending in the z-axis direction when the cooling fan 10 is operated are indicated by a thin line, while the outlines of members which are not driven to rotate are indicated by a thick line.

The configuration of the cooling fan 10 of this embodiment has been described above with reference to FIG. 4. As described above, in this embodiment, the shaft member 120 penetrates through the case 170 in the vertical direction (first direction), and the opposite ends of the shaft member 120 are fixedly joined to the inner surfaces of the upper and lower housing partition walls 210a and 210b which are located above and below the case 170. Alternatively, the shaft member 120 is extended in the case 170 in the first direction, and the opposite ends of the shaft member 120 are fixedly joined to the inner surfaces of the upper and lower case partition walls 170a and 170b. The fan 110 is allowed to rotate around the axis of rotation extending in the first direction relative to the shaft member 120. Thus, in the cooling fan 10 of this embodiment, the shaft member 120 has the function of serving as a shaft for supporting the fan 110 for rotation, and the function of serving as a support member for supporting, in the vertical direction, the housing of the portable electronic apparatus in which the case 170 and/or the cooling fan 10 are provided.

Note that, in this embodiment, members may be fixedly joined to each other using any of various known techniques. For example, members may be fixedly joined to each other by welding or using various adhesives, double-sided tape, etc. Alternatively, members which are fixedly joined to each other may be integrally formed. Thus, in this embodiment, the technique of fixedly joining members together is not particularly limited. Any preferable joining technique that can join members with a predetermined strength may be suitably selected.

### [2-2. Advantages of Cooling Fan of This Embodiment]

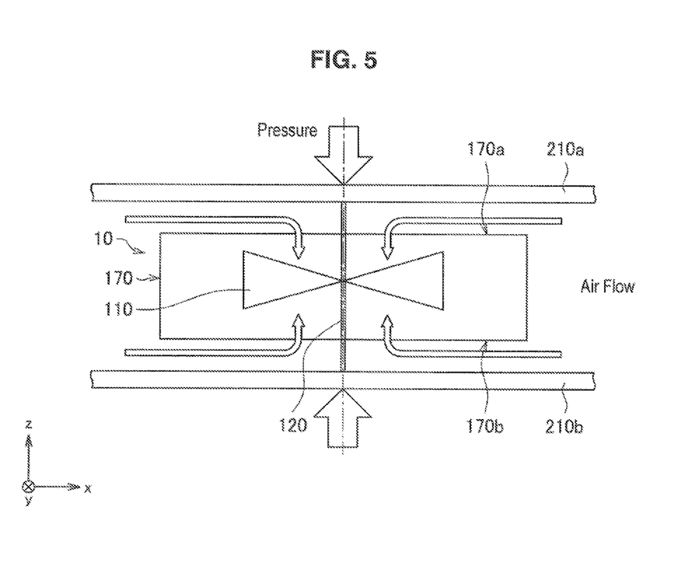

Next, advantages obtained by the cooling fan 10 of this embodiment of FIG. 4 will be described with reference to FIG. 5.

FIG. 5 is a diagram for describing advantages obtained by the cooling fan 10 of this embodiment. FIG. 5 schematically shows a simplification of the cooling fan 10 of FIG. 4. Specifically, in FIG. 5, of the components of the cooling fan 10, only the fan 110, the shaft member 120, and the case 170 are schematically shown. FIG. 5 also shows the upper and lower housing partition walls 210a and 210b of the housing of the portable electronic apparatus housing the cooling fan 10, that are located above and below the cooling fan 10.

Firstly, a case where external pressure is exerted from the vertical direction on the housing of the portable electronic apparatus in which the cooling fan 10 of this embodiment is provided will be described. In FIG. 5, external pressure exerted on the upper and lower housing partition walls 210a and 210b is schematically shown by arrows. As described in the above section [1-2. Study of Commonly Used Existing Cooling Fan], the portable electronic apparatus in which the cooling fan 10 is provided may be, for example, a notebook PC, and various operation means (operation units) for allowing the user to enter an operation input to the notebook PC may be provided on an upper surface of the upper housing partition wall 210a. Here, the operation means is an input interface which receives the user's operation input, such as a keyboard, a touchpad, a button, etc. When the notebook PC is used, the keyboard, touchpad, etc. is struck or pressed by the user. When the notebook PC is placed on a desk etc. in use, a vertical reaction force may be exerted on the lower housing partition wall 210b due to the user's operation, such as striking, pressing, etc. Thus, when the portable electronic apparatus, such as a notebook PC etc., is used, external pressure may be exerted on the upper and lower housing partition walls 210a and 210b.

Here, as described above with reference to FIGS. 2A and 2B, in the commonly used existing cooling fan 60, the shaft member 620 supports only the lower case partition wall 670b, and therefore, the case 670 is not rigid enough against a force from the vertical direction, so that the case 670 may also be deformed due to external pressure exerted on the upper and lower housing partition walls 210a and 210b, and therefore, the normal operation of the cooling fan 60 is likely to be hindered or prevented. On the other hand, as described above with reference to FIG. 4, in the cooling fan 10 of this embodiment, the opposite ends of the shaft member 120 are fixedly joined to the inner surfaces of the upper and lower housing partition walls 210a and 210b. The shaft member 120 supports the upper and lower housing partition walls 210a and 210b in the vertical direction, resulting in an improvement in the rigidity of the housing against a force exerted from the vertical direction. Therefore, even when external pressure is exerted on the upper and lower housing partition walls 210a and 210b from the vertical direction, the upper and lower housing partition walls 210a and 210b are less likely to be deformed. Therefore, in this embodiment, the possibility that the deformation of the upper and lower housing partition walls 210a and 210b due to external pressure has an influence on the cooling fan 10 provided in the housing is reduced, and therefore, the normal operation of the cooling fan 10 is maintained.

Note that, in this embodiment, of the partition walls of the case 170, the upper case partition wall 170a may not be provided in some applications of the cooling fan 10. When the upper case partition wall 170a is not provided, the case 170 is open at the top. In this case, if the upper housing partition wall 210a is deformed due to external pressure, the deformed upper housing partition wall 210a may be directly in contact with the fan 110, the shaft member 120, etc., leading to a more serious operational failure. In this embodiment, the opposite ends of the shaft member 120 are fixedly joined to the inner surfaces of the upper and lower housing partition walls 210a and 210b, and therefore, the deformation of the upper and lower housing partition walls 210a and 210b due to external pressure is reduced or prevented, whereby such a serious operational failure is less likely to occur.

Also, as described above, in this embodiment, the shaft member 120 may not penetrate through the case 170, and in the case 170, the opposite ends of the shaft member 120 may be fixedly joined to the respective corresponding inner surfaces of the upper and lower case partition walls 170a and 170b. The shaft member 120 supports the upper and lower case partition walls 170a and 170b in the vertical direction, and therefore, the rigidity of the case 170 against a force exerted from the vertical direction is improved. Therefore, even if the upper and lower housing partition walls 210a and 210b are deformed due to external pressure, so that a force is exerted on the case 170 due to the deformation, the case 170 is less likely to be deformed. Therefore, in this embodiment, the influence of the deformation of the upper and lower housing partition walls 210a and 210b due to external pressure on a component in the case 170 is reduced, and therefore, the normal operation of the cooling fan 10 is guaranteed.

Moreover, in this embodiment, the upper end (one end) of the shaft member 120 may be fixedly joined to the upper case partition wall 170a and/or the upper housing partition wall 210a, and the lower end (the other end) of the shaft member 120 may be fixedly joined to the lower case partition wall 170b and/or the lower housing partition wall 210b. For example, one end of the shaft member 120 may be fixedly joined to the upper case partition wall 170a or the lower case partition wall 170b, while the other end of the shaft member 120 may be fixedly joined to the upper housing partition wall 210a or the lower housing partition wall 210b. Thus, the shaft member 120 supports, in the vertical direction, the case 170 and/or the housing of the portable electronic apparatus in which the cooling fan 10 is provided, whereby the rigidity of the case 170 and/or the housing against a force exerted from the vertical direction is improved. Therefore, when external pressure is applied to the upper and lower housing partition walls 210a and 210b, the deformation of the case 170 and/or the housing is reduced or prevented, and therefore, the normal operation of the cooling fan 10 is maintained.

Next, the drawing in of air by the cooling fan 10 of this embodiment will be discussed. As described in the above section [1-2. Study of Commonly Used Existing Cooling Fan], in the commonly used existing cooling fan 60, the buffer member 720 is provided between the case 670 and each of the upper and lower housing partition walls 710a and 710b, and therefore, the buffer member 720 may narrow or block the air flow channel, so that air is unlikely to be smoothly drawn in. On the other hand, as described above, in the cooling fan 10 of this embodiment, the opposite ends of the shaft member 120 are fixedly joined to the inner surfaces of the upper and lower housing partition walls 210a and 210b, so that the shaft member 120 has the function of serving as a support member for supporting the housing in the vertical direction. Therefore, in this embodiment, it is not necessary to provide an additional support member, such as the buffer member 720, for reducing or preventing the deformation of the upper and lower housing partition walls 710a and 710b. Thus, in this embodiment, it is not necessary to provide a member which would narrow or block the flow channel, such as the buffer member 720, and therefore, air is smoothly drawn into the cooling fan 10, so that the thermal dissipation efficiency (cooling efficiency) does not decrease. In FIG. 5, a portion of such flow of air around the cooling fan 10 is shown by arrows.

### <3. Summary>

As described above, in this embodiment, the following advantages are obtained.

In this embodiment, the opposite ends of the shaft member 120 inserted in the fan 110 are fixedly joined to the inner surfaces of the first and second partition walls located at upper and lower portions of the fan 110 on the opposite sides in the first direction in which the shaft member 120 extends. The first and second partition walls may be the upper and lower partition walls of the case 170 of the cooling fan 10, or the upper and lower partition walls of the housing of the portable electronic apparatus in which the cooling fan 10 is provided. Thus, the shaft member 120 has the function of serving as a support member for supporting the fan 110 for rotation and supporting the case 170 and/or the housing in the vertical direction. Therefore, the shaft member 120 improves the rigidity of the case 170 and/or the housing against a force exerted from the vertical direction. Therefore, the deformation of the case 170 and/or the housing due to external pressure exerted from the vertical direction is reduced or prevented, whereby the normal operation of the cooling fan 10 is maintained.

Also, in this embodiment, the portable electronic apparatus in which the cooling fan 10 is provided may be a notebook PC. When the portable electronic apparatus is a notebook PC, an operation means for allowing the user to enter an operation input to the notebook PC may be provided on an upper surface (outer surface) of the upper partition wall of the housing. Such operation means may be, for example, a keyboard, a touchpad, etc., and may be struck or pressed by the user during operation. As described above, in this embodiment, the deformation of the case 170 or the housing due to external pressure in the vertical direction is reduced or prevented, and therefore, the normal operation of the cooling fan 10 is not hindered due to external pressure which is exerted by the user's operation on the housing of the notebook PC.

Also, in this embodiment, as described above, the shaft member 120 supports, in the vertical direction, the housing of the portable electronic apparatus in which the cooling fan 10 is provided. Therefore, the rigidity of the housing can be improved without providing an additional support member between the case 170 of the cooling fan 10 and the housing. Therefore, the flow channel around the cooling fan 10 is not narrowed or blocked by such an additional support member, and therefore, the efficiency of drawing in and expelling air of the cooling fan 10 does not decrease.

Thus, the reliability of the operation of the cooling fan 10 of this embodiment against external pressure can be improved.

It should be understood by those skilled in the art that various modifications, combinations, sub-combinations and alterations may occur depending on design requirements and other factors insofar as they are within the scope of the appended claims or the equivalents thereof.

For example, in the foregoing, as an example rotation drive device, a cooling fan which is provided in a housing of a portable electronic apparatus, such as a notebook PC etc., has been described. This embodiment is not limited to such an example. The rotation drive device of this embodiment may be any device that has a configuration in which a rotating object supported by a shaft member is housed in a case or a housing. For example, the rotation drive device of this embodiment may be a larger-size device, such as a mechanical fan, a ventilation fan, etc.

Additionally, the present technology may also be configured as below.

(1) A rotation drive device including:

a shaft member extending in a first direction; and

a rotating object configured to allow the shaft member to be inserted in the rotating object, and configured to rotate around an axis of rotation extending in the first direction relative to the shaft member,

wherein opposite ends of the shaft member are fixedly joined to respective inner surfaces of a first partition wall and a second partition wall located on the opposite sides in the first direction of the rotating object.

(2) The rotation drive device according to (1),

wherein the shaft member penetrates, in the first direction, through a case housing the rotating object, and

wherein the first partition wall and the second partition wall are partition walls of a housing of a portable electronic apparatus housing the rotation drive device, the partition walls being located on the opposite sides in the first direction.

(3) The rotation drive device according to (1),

wherein the first partition wall and the second partition wall are partition walls of a case housing the rotating object, the partition walls being located on the opposite sides in the first direction.

(4) The rotation drive device according to (1),

wherein the first partition wall is a partition wall of a housing of a portable electronic apparatus housing the rotation drive device, the partition wall being located on one side in the first direction, and

wherein the second partition wall is a partition wall of a case housing the rotating object, the partition wall being located on the opposite side from the first partition wall in the first direction.

(5) The rotation drive device according to any one of (1) to (4),

wherein the rotating object includes at least one blade in an outer circumferential portion of the rotating object,

wherein a case housing the rotating object includes a partition wall on at least one of the opposite sides in the first direction, and an opening for drawing in air in a portion of the partition wall, and

wherein the rotating object is driven to rotate around the axis of rotation extending in the first direction in a manner that the rotating object draws in air from the first direction through the opening of the case and expels the air in a second direction different from the first direction.

(6) The rotation drive device according to any one of (1) to (5),

wherein the rotation drive device is a cooling fan which is provided in a housing of a portable electronic apparatus to dissipate heat from an inside of the housing of the portable electronic apparatus.

(7) The rotation drive device according to (6),

wherein the portable electronic apparatus is a notebook PC,

wherein the first partition wall and the second partition wall are partition walls of a housing of the notebook PC located on the opposite sides in the first direction, and

wherein an operation unit for allowing the user to enter an operation input to the notebook PC is provided on an outer surface of the first partition wall or the second partition wall.

What is claimed is:

1. A rotation drive device comprising:
a shaft member extending in a first direction; and
a rotating object configured to allow the shaft member to be inserted in the rotating object, and configured to rotate around an axis of rotation extending in the first direction relative to the shaft member,
wherein opposite ends of the shaft member are fixedly joined to respective inner surfaces of a first partition wall and a second partition wall located on the opposite sides in the first direction of the rotating object.

2. The rotation drive device according to claim 1,
wherein the shaft member penetrates, in the first direction, through a case housing the rotating object, and
wherein the first partition wall and the second partition wall are partition walls of a housing of a portable electronic apparatus housing the rotation drive device, the partition walls being located on the opposite sides in the first direction.

3. The rotation drive device according to claim 1,
wherein the first partition wall and the second partition wall are partition walls of a case housing the rotating object, the partition walls being located on the opposite sides in the first direction.

4. The rotation drive device according to claim 1,
wherein the first partition wall is a partition wall of a housing of a portable electronic apparatus housing the rotation drive device, the partition wall being located on one side in the first direction, and
wherein the second partition wall is a partition wall of a case housing the rotating object, the partition wall being located on the opposite side from the first partition wall in the first direction.

5. The rotation drive device according to claim 1,
wherein the rotating object includes at least one blade in an outer circumferential portion of the rotating object,
wherein a case housing the rotating object includes a partition wall on at least one of the opposite sides in the first direction, and an opening for drawing in air in a portion of the partition wall, and
wherein the rotating object is driven to rotate around the axis of rotation extending in the first direction in a manner that the rotating object draws in air from the first direction through the opening of the case and expels the air in a second direction different from the first direction.

6. The rotation drive device according to claim 5,
wherein the rotation drive device is a cooling fan which is provided in a housing of a portable electronic apparatus to dissipate heat from an inside of the housing of the portable electronic apparatus.

7. The rotation drive device according to claim 6,
wherein the portable electronic apparatus is a notebook PC,
wherein the first partition wall and the second partition wall are partition walls of a housing of the notebook PC located on the opposite sides in the first direction, and
wherein an operation unit for allowing the user to enter an operation input to the notebook PC is provided on an outer surface of the first partition wall or the second partition wall.
